(19) United States
(12) Patent Application Publication
(10) Pub. No.: US 2003/0132863 A1
(43) Pub. Date: Jul. 17, 2003

(54) Articulated, rotatable expandable and contractible keyboard device

(76) Inventor: Roy J. Lahr, Los Angeles, CA (US)

Correspondence Address: KENYON & KENYON, ONE BROADWAY, NEW YORK, NY, 10004, US

(21) Appl. No.: 10/310,530

(22) Filed: Dec. 5, 2002

Related U.S. Application Data
(60) Provisional application No. 60/337,421, filed on Dec. 6, 2001.

(51) Int. Cl. H03M 11/00; H03K 17/94

(52) U.S. Cl. 341/22

(57) ABSTRACT

An articulated, rotatable keyboard device of an electronic data device is articulable and rotatable between a storage position, in which the keyboard device does not substantially increase the form factor of the electronic data device, and a use position. The keyboard device may be expandable and contractible. In a contracted state, the keyboard device may have a size and configuration adapted to permit single-finger typing, and in an expanded state, the keyboard device may have a size and configuration adapted to permit touch-typing.

### CROSS-REFERENCE TO RELATED APPLICATIONS

The present application claims the benefit of U.S. Provisional Patent Application No. 60/337,421, filed on Dec. 6, 2001, which is expressly incorporated herein in its entirety by reference thereto.

### FIELD OF THE INVENTION

The present invention relates to an articulated, rotatable expandable and contractible keyboard device.

### BACKGROUND INFORMATION

Expandable and contractible keyboard devices are described, for example, in U.S. patent application Ser. No. 09/558,866, entitled “Expandable and Contractible Keyboard with Adjustable Key Sizes,” and U.S. patent application Publication No. 2001/0028712, entitled “Expandable and Contractible Keyboard with Adjustable Key Sizes,” each of which is expressly incorporated herein in its entirety by reference thereto.

Electronic data devices, such as cellular telephones, electronic organizers, personal digital assistants, etc., may be provided with an integrated or detachable keyboard device. However, detachable keyboard devices commonly extend from one side, e.g., the bottom, of the data device and are stored separately when not in use. Integrated keyboards generally increase the size of the data device.

It is therefore an object of the present invention to provide a keyboard device for an electronic data device, the keyboard device being articulable and rotatable between a storage position and a use position.

It is another object of the present invention to provide such an articulated and rotatable keyboard device that is expandable and contractible between a contracted state, e.g., having a size and configuration suitable for single-finger typing, and an expanded state, e.g., having a size and configuration for touch-typing.

It is a further object of the present invention to provide an electronic data device, which includes the articulated and rotatable keyboard device or the articulated, rotatable expandable and contractible keyboard device.

### SUMMARY

The above and other beneficial objects of the present invention are achieved by providing a keyboard device as described herein.

According to one example embodiment of the present invention, a keyboard device is articulable and rotatable between a storage position, in which the form factor of an attached electronic data device is not substantially increased, and a use position.

According to another example embodiment of the present invention, such keyboard device, in the use position, is expandable between a contracted state, e.g., having a size and configuration adapted to permit single-finger typing, and an expanded state, e.g., having a size and configuration adapted to permit touch-typing.

According to an example embodiment of the present invention, the keyboard device for an electronic device includes a keyboard housing extendable between a contracted position and an expanded position and a plurality of key elements. The pitch between adjacent key elements is proportional to the extension of the keyboard housing, and the keyboard housing is arranged to at least one of articulate and rotate relative to the electronic device between a storage position and a use position. The keyboard housing in the storage position does not substantially increase a form factor of the electronic device.

The keyboard housing may include a hub configured to at least one of articulatably and rotatably connect the keyboard housing to the electronic device, and the hub may be arranged to be received in a slot of the electronic device. The key elements may be arranged behind the electronic device when the keyboard housing is arranged in the storage position. The keyboard housing may be slidably and a rotatably connected to the electronic device, and the key elements may be electronically and logically connected to the electronic device.

The key elements may include an alphanumeric keyboard layout, e.g., a QWERTY keyboard arrangement, a non-US variation thereof, e.g., AZERTY, a telephone keypad arrangement, a calculator keypad arrangement, etc. The keyboard housing in the use position may extend from a side of the electronic device or may extend from a bottom of the electronic device.

The key elements may be arranged for single-finger data entry in the contracted position and for touch-typing data entry in the extended position. The keyboard device may include a web stretchable in accordance with the extension of the keyboard housing, and the key elements may be arranged on the web.

### BRIEF DESCRIPTION OF THE DRAWINGS

FIG. 1 is a top plan view of an example embodiment of an electronic data device.

FIG. 2 is a side elevational view of the electronic data device illustrated in FIG. 1.

FIG. 3 is a bottom plan view of the electronic data device illustrated in FIGS. 1 and 2.

FIG. 4 is a top plan view of a keyboard device according to the present invention.

FIG. 5 is a top plan view of the electronic data device illustrated in FIGS. 1 to 3 including the keyboard device illustrated in FIG. 4.

FIG. 6 is a top plan view of the electronic data device illustrated in FIGS. 1 to 3 including the keyboard device illustrated in FIG. 4 in a contracted state.

FIG. 7 is a top plan view of the electronic data device illustrated in FIGS. 1 to 3 including the keyboard device illustrated in FIG. 4 in an expanded state.

### DETAILED DESCRIPTION

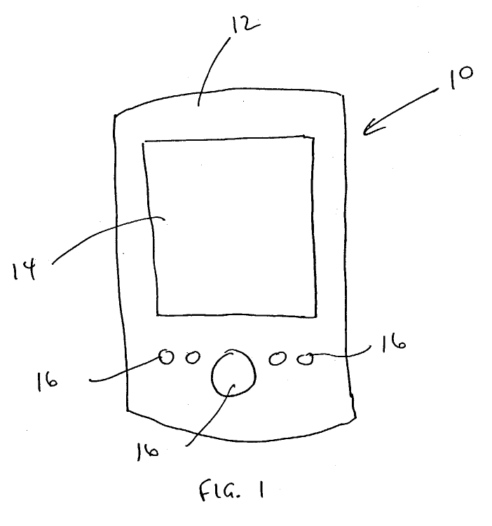

FIG. 1 is a top plan view of an example embodiment of an electronic data device 10. FIG. 1 illustrates the electronic data device 10 in the form of a personal digital assistant (“PDA”). It should be appreciated that the electronic data device 10 is illustrated in FIG. 1 as a PDA merely as one example of an electronic data device and that any other form of electronic data device, including, for example, a cellular telephone, a cordless telephone, a pager device, a text messaging device, a wireless device, an electronic organizer, a palm-top computer, a laptop computer, etc., may be provided. The electronic data device 10 may include a housing 12, a display device 14 and control elements 16. Disposed on a bottom surface of the electronic data device 10 is a keyboard device 20. FIG. 1 illustrates the keyboard device 20 in a storage position, in which the keyboard device 20 does not substantially increase the form factor of the electronic data device 10.

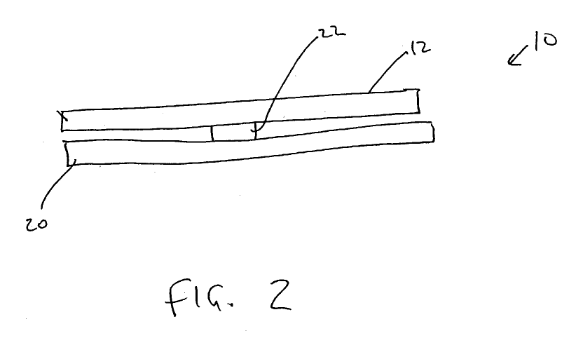

FIG. 2 is a side elevational view of electronic data device 10. As illustrated in FIG. 2, keyboard device 20 is disposed on a bottom surface of the electronic data device 10 and is connected to the electronic data device 10 via hub 22.

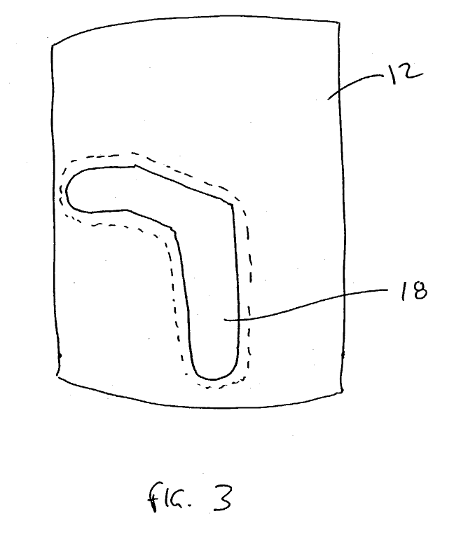

FIG. 3 is a bottom plan view of the housing 12. A channel 18 is provided in the bottom surface of housing 12 and is adapted by size and configuration to receive hub 22 of keyboard device 20 in slidable and rotatable engagement.

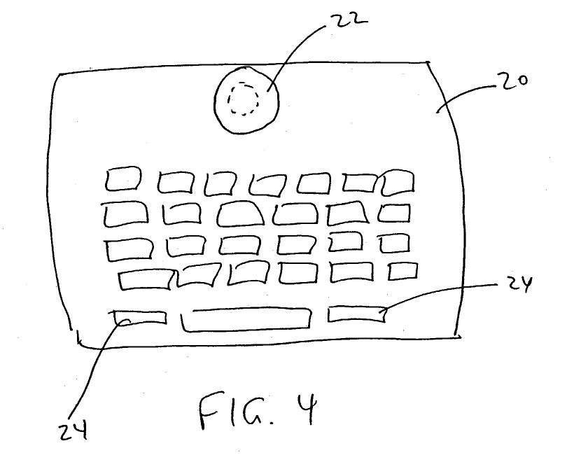

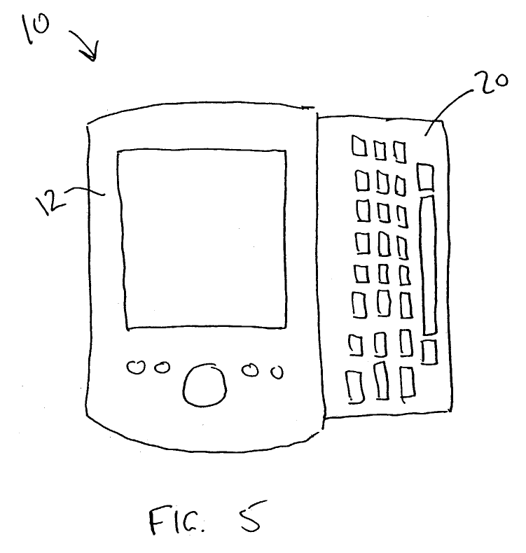

FIG. 4 is a top plan view of the keyboard device 20. Keyboard device 20 includes hub 22 having a size and configuration to slidably and rotatably engage with the channel 18 of the bottom surface of housing 12. Keyboard device 20 further includes a plurality of key elements 24, which may, for example, correspond to an alphanumeric keyboard layout, e.g., a standard QWERTY keyboard arrangement or a non-US variation thereof, e.g., AZERTY, a telephone keypad arrangement, a calculator keypad arrangement, a numeric keypad arrangement, etc. The keyboard device 20, by virtue of the slidable and rotatable engagement of hub 22 and channel 18, permits the keyboard device 20 to be articulated and rotated between a storage position behind the housing 12, in which storage position the keyboard device 20 does not substantially increase the form factor of the electronic data device 10, and a use position, which is further illustrated in FIGS. 5 to 7. Keyboard device 20 and/or hub 22 may include electronic elements, such as, for example, contacts, leads, transceivers, transducers, wires, wireless devices, etc., configured to provide electronic and logic communication between the keyboard device 20 and the electronic components of the electronic data device 10.

FIG. 5 illustrates the electronic data device 10 in which the keyboard device 20 is in an intermediate position between the storage position and the use position.

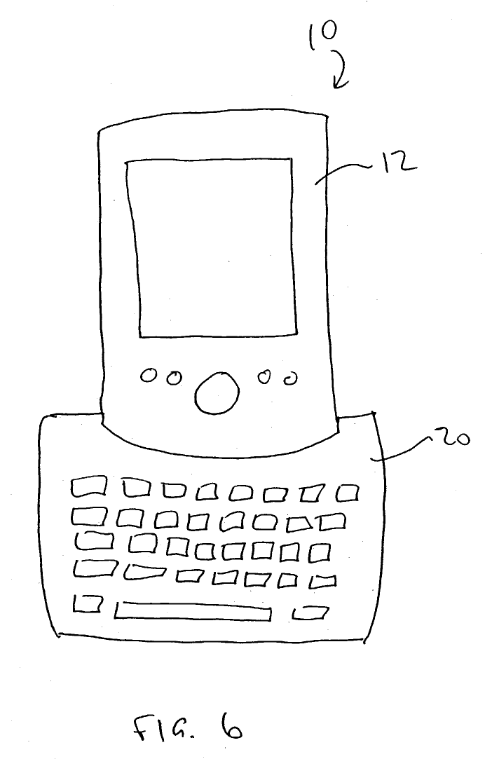

FIG. 6 illustrates the electronic data device 10 in which the keyboard device 20 is in the use position.

The keyboard device 20 may be configured as an expandable and contractible keyboard device as described, for example, in U.S. patent application Ser. No. 09/558,866, entitled “Expandable and Contractible Keyboard with Adjustable Key Sizes,” and U.S. patent application Publication No. 2001/0028712, entitled “Expandable and Contractible Keyboard with Adjustable Key Sizes,” each of which is expressly incorporated herein in its entirety by reference thereto. Thus, FIG. 6 illustrates the keyboard device 20 in the use position and in a contracted state. In the contracted state, the keyboard device 20 may have a size and configuration, e.g., adapted to permit single-finger typing.

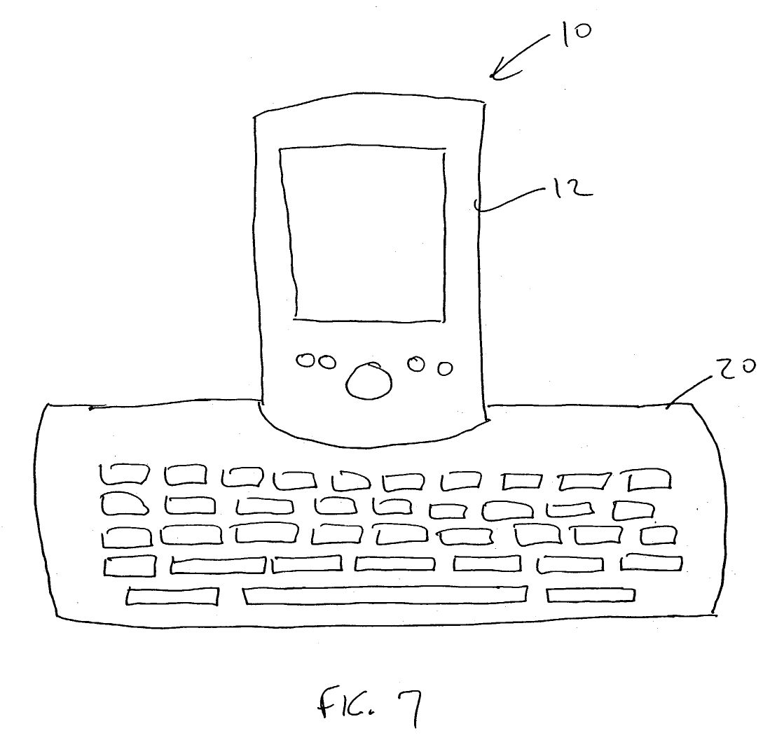

FIG. 7 illustrates the keyboard device 20 in the use position and in an expanded state. In the expanded state, the keyboard device 20 may have a size and configuration, e.g., adapted to permit touch-typing.

It should be appreciated that the keyboard device 20 may be integral to the electronic data device 10. Alternatively, the keyboard device 20 may be detachable from the electronic data device 10.

What is claimed is:

1. A keyboard device for an electronic device, comprising:
a keyboard housing extendable between a contracted position and an expanded position; and
a plurality of key elements, a pitch between adjacent key elements proportional to the extension of the keyboard housing;
wherein the keyboard housing is arranged to at least one of articulate and rotate relative to the electronic device between a storage position and a use position; and
wherein the keyboard housing in the storage position does not substantially increase a form factor of the electronic device.

2. The keyboard device according to claim 1, wherein the keyboard housing includes a hub configured to at least one of articulatably and rotatably connect the keyboard housing to the electronic device.

3. The keyboard device according to claim 1, wherein the key elements are arranged behind the electronic device when the keyboard housing is arranged in the storage position.

4. The keyboard device according to claim 1, wherein the keyboard housing is slidably and a rotatably connected to the electronic device.

5. The keyboard device according to claim 1, wherein the key elements are electronically and logically connected to the electronic device.

6. The keyboard device according to claim 1, wherein the plurality of key elements includes a QWERTY keyboard arrangement.

7. The keyboard device according to claim 1, wherein the plurality of key elements includes a telephone keypad arrangement.

8. The keyboard device according to claim 1, wherein the plurality of key elements includes a calculator keypad arrangement.

9. The keyboard device according to claim 1, wherein the keyboard housing in the use position extends from a side of the electronic device.

10. The keyboard device according to claim 1, wherein the keyboard housing in the use position extends from a bottom of the electronic device.

11. The keyboard device according to claim 2, wherein the hub is arranged to be received in a slot of the electronic device.

12. The keyboard device according to claim 1, wherein the key elements are arranged for single-finger data entry in the contracted position and for touch-typing data entry in the extended position.

13. The keyboard device according to claim 1, further comprising a web stretchable in accordance with the extension of the keyboard housing, the key elements arranged on the web.

14. The keyboard device according to claim 1, wherein the plurality of key elements includes an alphanumeric keyboard layout.
